(19) United States
(12) Patent Application Publication
(10) Pub. No.: US 2023/0223285 A1
(43) Pub. Date: Jul. 13, 2023

(54) METHOD OF MANUFACTURING SEMICONDUCTOR DEVICE, RECORDING MEDIUM, AND SUBSTRATE PROCESSING APPARATUS

(71) Applicant: KOKUSAI ELECTRIC CORPORATION, Tokyo (JP)

(72) Inventors: Yuta TACHI, Toyama (JP); Takayuki KAWAGISHI, Toyama (JP); Kazuyoshi YAMAMOTO, Toyama (JP); Ryuichi KAJI, Toyama (JP); Masanori SAKAI, Toyama (JP)

(73) Assignee: KOKUSAI ELECTRIC CORPORATION, Tokyo (JP)

(21) Appl. No.: 18/124,799

(22) Filed: Mar. 22, 2023

Related U.S. Application Data
(63) Continuation of application No. PCT/JP2021/026139, filed on Jul. 12, 2021.

(51) Int. Cl. H01L 21/67; G01M 13/028; G01H 1/00

(52) U.S. Cl. CPC H01L 21/67253; G01M 13/028; G01H 1/003

(57) ABSTRACT

Provided is a technique of processing a substrate by executing a process recipe including a plurality of steps, the technique including: (a) acquiring vibration data of a member that exhausts an atmosphere in a process chamber that processes the substrate from a vibration sensor while executing the process recipe; and (b) detecting presence of an abnormality sign in a case where a ratio between a magnitude of vibration at a rotation frequency of the member and a magnitude of vibration at a comparison frequency that is an integral multiple of the rotation frequency exceeds a preset abnormality sign threshold on the basis of the acquired vibration data.

### CROSS-REFERENCE TO RELATED APPLICATIONS

This application is a Bypass Continuation Application of PCT International Application No. PCT/JP2021/026139, filed Jul. 12, 2021, which is based upon and claims the benefit of priority from PCT International Application No. PCT/JP2020/035760, filed Sep. 23, 2020, the entire disclosure of which are incorporated herein by reference.

### BACKGROUND

### Field

The present disclosure relates to a method of manufacturing a semiconductor device, a recording medium, and a substrate processing apparatus.

### Description of the Related Art

A substrate processing apparatus or a method of manufacturing semiconductor device in which a thin film is formed on a substrate such as a silicon wafer to manufacture a semiconductor device is known. For example, in related arts, there is a method of manufacturing a semiconductor device in which a source gas and a reactant gas that reacts with the source gas are sequentially supplied to a process chamber that stores a substrate to form a thin film on the substrate stored in the process chamber.

In general, such a substrate processing apparatus includes various members such as a vacuum pump that vacuum-exhausts the inside of a process chamber, a mass flow controller that controls a flow rate of a reactive gas or the like, an on-off valve, a pressure gauge, a heater that heats the process chamber, and a transport mechanism that transports a substrate.

Since each of the various members gradually deteriorates and fails as it is used, replacement with a new member is required.

Here, in a case where a member is used until failure, all substrates processed by the substrate processing apparatus at the time of failure may be defective, and the substrates and production time at the time of failure may be lost. In addition, in a case where replacement is periodically performed before failure, it is necessary to perform replacement in a period in which failure does not occur, that is, every short period with a sufficient margin. Therefore, a frequency of replacement of a member increases, which may lead to an increase in operation cost.

### SUMMARY

According to the present disclosure, there is provided a technique capable of detecting an abnormality sign of a member.

An aspect of the present disclosure provides a technique of processing a substrate by executing a process recipe including a plurality of steps, the technique including: (a) acquiring vibration data of a member that exhausts an atmosphere in a process chamber that processes the substrate from a vibration sensor while executing the process recipe; and (b) detecting presence of an abnormality sign in a case where a ratio between a magnitude of vibration at a rotation frequency of the member and a magnitude of vibration at a comparison rotation frequency that is an integral multiple of the rotation frequency exceeds a preset abnormality sign threshold on the basis of the acquired vibration data.

### BRIEF DESCRIPTION OF THE DRAWINGS

FIG. 1 is a perspective view illustrating a schematic configuration of a substrate processing apparatus according to an embodiment.

FIG. 2 is an elevation sectional view illustrating a schematic configuration of a processing furnace of the substrate processing apparatus according to the embodiment.

FIG. 3 is a block diagram illustrating a schematic configuration of a main controller of the substrate processing apparatus according to the embodiment.

FIG. 4 is a flowchart illustrating a substrate processing step in a case where the substrate processing apparatus according to the embodiment is used as a semiconductor manufacturing apparatus.

FIG. 5 is a block diagram illustrating a control system of the substrate processing apparatus according to the embodiment.

FIG. 6 is an explanatory diagram illustrating a determination procedure of detecting an abnormality sign of a member according to the embodiment.

FIG. 7A is a graph illustrating an example in which a power spectrum ratio serving as an index of abnormality sign detection of a member according to the embodiment on the X-axis is indicated in time series.

FIG. 7B is a graph illustrating an example in which a power spectrum ratio serving as an index of abnormality sign detection of a member according to the embodiment on the Y-axis is indicated in time series.

FIG. 7C is a graph illustrating an example in which a power spectrum ratio serving as an index of abnormality sign detection of a member according to the embodiment on the Z-axis is indicated in time series.

FIG. 8 is a block diagram illustrating a part of a control system of a substrate processing apparatus according to another embodiment.

FIG. 9 is a timing chart of vibration data acquisition by the substrate processing apparatus according to the other embodiment.

### DETAILED DESCRIPTION

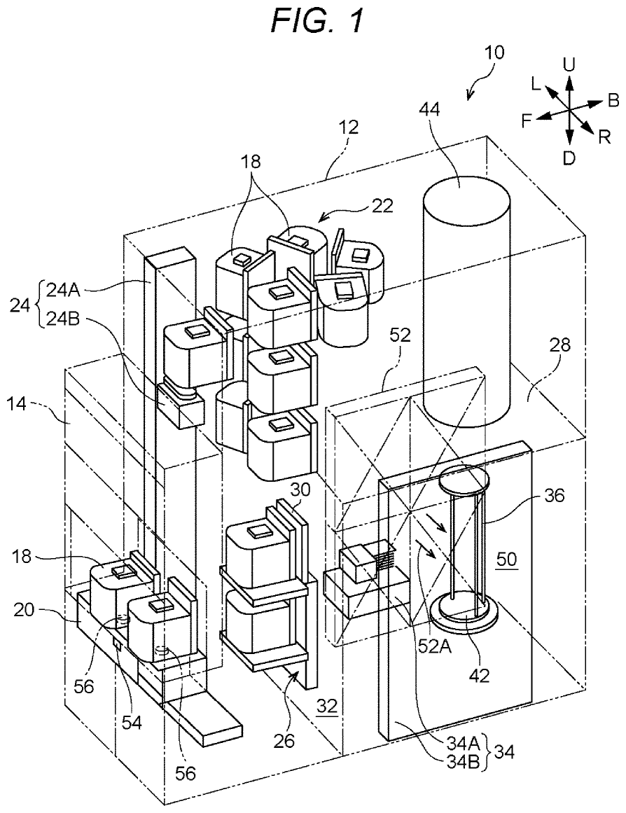

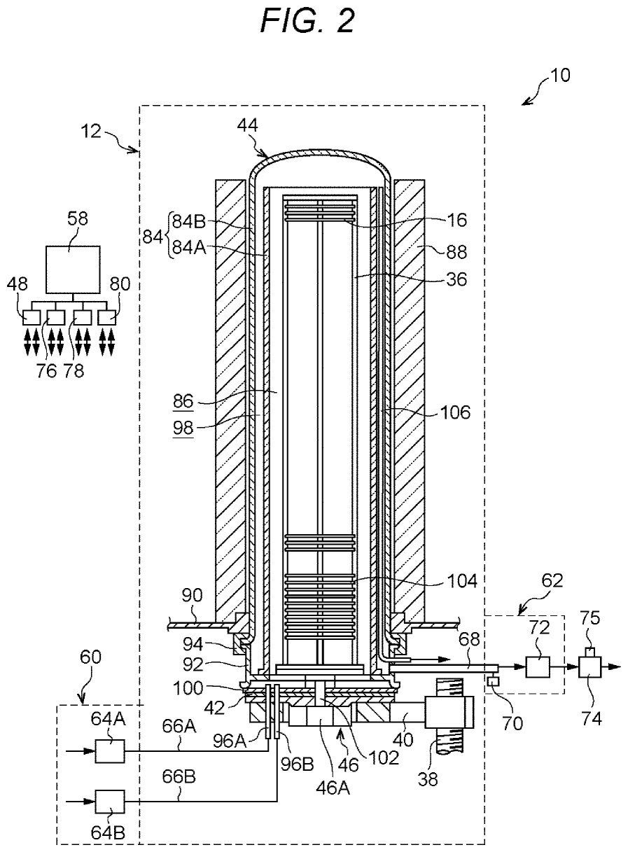

Hereinafter, a method of manufacturing a semiconductor device, a sign detection program, and a substrate processing apparatus according to an embodiment of the present disclosure will be described. Note that, in FIG. 1, an arrow F indicates a front direction of the substrate processing apparatus, an arrow B indicates a rear surface direction, an arrow R indicates a right direction, an arrow L indicates a left direction, an arrow U indicates an upward direction, and an arrow D indicates a downward direction. Hereinafter, a configuration of a substrate processing apparatus 10 will be described with reference to FIGS. 1 and 2. The drawings used in the following description are all schematic, and a dimensional relationship among elements, a ratio among the elements, and the like illustrated in the drawings do not necessarily coincide with actual ones. In addition, a dimensional relationship among elements, a ratio among the elements, and the like do not necessarily coincide among the plurality of drawings.

### <General Configuration of Substrate Processing Apparatus>

As illustrated in FIG. 1, the substrate processing apparatus 10 includes a housing 12 formed of a pressure-resistant container. A front wall of the housing 12 has an opening formed so as to be able to perform maintenance, and this opening has a pair of front doors 14 as an entry mechanism that opens and closes the opening. Note that, in the substrate processing apparatus 10, a pod (substrate container) 18 serving as a substrate storing container storing a substrate (wafer) 16 (see FIG. 2) made of silicon or the like described later is used as a carrier that carries the substrate 16 to the inside and outside of the housing 12.

The front wall of the housing 12 has a pod loading/unloading port opened such that the inside and the outside of the housing 12 communicate with each other. A load port 20 is disposed in the pod loading/unloading port. It is configured such that the pod 18 is placed on the load port 20 and the position of the pod 18 is aligned.

A rotary pod shelf 22 is disposed in an upper portion of a substantially central portion in the housing 12. It is configured such that a plurality of the pods 18 is stored on the rotary pod shelf 22. The rotary pod shelf 22 includes: a column that is erected vertically and rotated in a horizontal plane; and a plurality of shelf boards radially supported at positions of upper, middle, and lower stages by the column.

A pod carry device 24 is disposed between the load port 20 and the rotary pod shelf 22 in the housing 12. The pod carry device 24 includes a pod elevator 24A and a pod carry mechanism 24B that can be elevated while holding the pod 18. It is configured such that the pod 18 is mutually carried among the load port 20, the rotary pod shelf 22, and a pod opener 26 described later by a continuous operation of the pod elevator 24A and the pod carry mechanism 24B.

In a lower portion in the housing 12, a sub housing 28 is disposed from a substantially central portion to a rear end in the housing 12. A pair of pod openers 26 that carries the substrate 16 into and out of the sub housing 28 is disposed on a front wall of the sub housing 28.

Each of the pod openers 26 includes a placing table on which the pod 18 is placed, and a cap attaching/detaching mechanism 30 that attaches and detaches a cap of the pod 18. The pod opener 26 is configured to open and close a substrate inlet/outlet of the pod 18 by attaching and detaching a lid of the pod 18 placed on the placing table by the cap attaching/detaching mechanism 30.

The sub housing 28 includes a transfer chamber 32 fluidly isolated from a space in which the pod carry device 24, the rotary pod shelf 22, and the like are disposed. A substrate transfer mechanism 34 is disposed in a front area of the transfer chamber 32. The substrate transfer mechanism 34 includes a substrate transfer device 34A that can rotate or linearly move the substrate 16 in the horizontal direction, and a substrate transfer device elevator 34B that elevates the substrate transfer device 34A.

The substrate transfer device elevator 34B is disposed between a right end of a front area of the transfer chamber 32 of the sub housing 28 and a right end of the housing 12. The substrate transfer device 34A includes a tweezer (not illustrated) serving as a holder of the substrate 16. It is configured such that a boat 36 serving as a substrate holder can be charged with the substrate 16 (charging) and the substrate 16 can be discharged from the boat 36 (discharging) by a continuous operation of the substrate transfer device elevator 34B and the substrate transfer device 34A.

As illustrated in FIG. 2, a boat elevator 38 that elevates the boat 36 is disposed in the sub housing 28 (transfer chamber 32). An arm 40 is connected to an elevating stage of the boat elevator 38, and a lid body (seal cap) 42 is horizontally installed in the arm 40. The lid body 42 is configured to vertically support the boat 36 and to be able to close a lower end of a process furnace 44 described later.

A carry mechanism that carries the substrate 16 mainly includes the rotary pod shelf 22, the pod carry device 24, the substrate transfer mechanism 34, and the boat 36 illustrated in FIG. 1, the boat elevator 38 illustrated in FIG. 2, and a rotation mechanism 46 described later. Each of the rotary pod shelf 22, the boat elevator 38, the pod carry device 24, the substrate transfer mechanism 34, the boat 36, and the rotation mechanism 46 is electrically connected to a carry controller 48 described later.

As illustrated in FIG. 1, the process furnace 44 is disposed above a standby portion 50 that stores the boat 36 and makes the boat 36 stand by. A clean unit 52 is disposed at a left end of the transfer chamber 32 on a side opposite to the substrate transfer device elevator 34B side. The clean unit 52 is configured to supply clean air 52A which is a cleaned atmosphere or an inert gas.

The clean air 52A blown out from the clean unit 52 flows around the substrate transfer device 34A and the boat 36 in the standby portion 50. Thereafter, the clean air 52A is sucked by a duct (not illustrated) and exhausted to the outside of the housing 12, or is circulated to a primary side (supply side) which is a suction side of the clean unit 52 and blown out again into the transfer chamber 32 by the clean unit 52.

Note that a plurality of apparatus covers (not illustrated) is attached to outer peripheries of the housing 12 and the sub housing 28 as a mechanism for entering the substrate processing apparatus 10. A maintenance person can enter the inside of the substrate processing apparatus 10 by detaching these apparatus covers at the time of maintenance work. At ends of the housing 12 and the sub housing 28 facing the apparatus covers, a door switch 54 (only the door switch 54 of the housing 12 is illustrated) serving as an entry sensor is disposed.

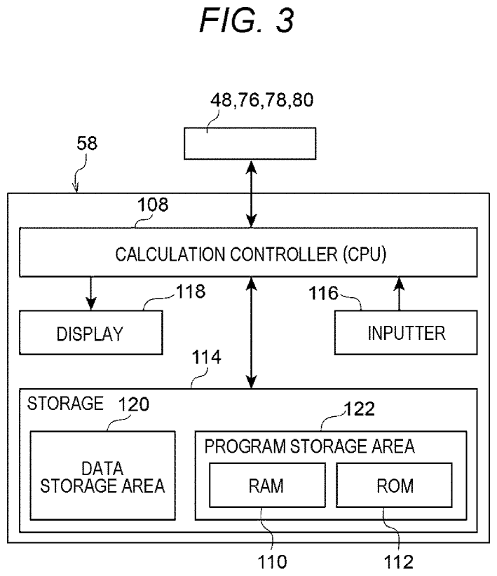

A substrate detection sensor 56 that detects placement of the pod 18 is disposed on the load port 20. The switch and sensor such as the door switch 54 and the substrate detection sensor 56 are electrically connected to a substrate processing apparatus controller 58 (see FIGS. 2 and 3) serving as a main controller described later.

As illustrated in FIG. 2, the substrate processing apparatus 10 includes a gas supply unit 60 and an exhaust unit 62 outside the housing 12. A processing gas supply system and a purge gas supply system are stored in the gas supply unit 60. The processing gas supply system includes a processing gas supply source and an on-off valve (not illustrated), a mass flow controller (hereinafter, abbreviated as MFC) 64A serving as a gas flow rate controller, and a processing gas supply pipe 66A. The purge gas supply system includes a purge gas supply source and an on-off valve (not illustrated), an MFC 64B, and a purge gas supply pipe 66B.

In the exhaust unit 62, a gas exhaust mechanism including an exhaust pipe 68, a pressure sensor 70 serving as a pressure detector, and a pressure regulator 72 constituted by, for example, an auto pressure controller (APC) valve is stored. Although not illustrated, a vacuum pump 74 serving as an exhaust device is connected to the exhaust pipe 68 on a downstream side of the exhaust unit 62. Note that the vacuum pump 74 may also be included in the gas exhaust mechanism. In addition, the exhaust unit 62 and the vacuum pump 74 may be disposed so as to be close to each other, for example, on the same floor, or the exhaust unit 62 and the vacuum pump 74 may be disposed so as to be separated from each other, for example, on different floors.

The vacuum pump 74 includes an acceleration sensor 75 serving as a vibration sensor. The acceleration sensor 75 measures vibration data of the vacuum pump 74. The acceleration sensor 75 is a three-axis acceleration sensor capable of measuring vibrations in three orthogonal axial directions, and is disposed so as to be able to measure vibrations in an up-down direction (direction of arrows U and D, hereinafter referred to as “Z-axis direction”) of the substrate processing apparatus 10, a left-right direction (direction of arrows R and L, hereinafter referred to as “Y-axis direction”) of the substrate processing apparatus 10, and a front-rear direction (direction of arrows F and B, hereinafter referred to as “X-axis direction”) of the substrate processing apparatus 10. Note that a rotation shaft of a rotor of the vacuum pump 74 is disposed in the Y-axis direction.

As illustrated in FIG. 2, the substrate processing apparatus controller 58 serving as a main controller is connected to the carry controller 48, a temperature controller 76, a pressure controller 78, and a gas supply controller 80. In addition, as illustrated in FIG. 5, the substrate processing apparatus controller 58 is connected to a sign detection controller 82 serving as a sign detector described later.

### <Configuration Processing Furnace>

As illustrated in FIG. 2, the process furnace 44 includes a reaction tube (process tube) 84. The reaction tube 84 includes an inner reaction tube 84A and an outer reaction tube 84B disposed outside the inner reaction tube 84A. The inner reaction tube 84A is formed in a cylindrical shape having open upper and lower ends, and a process chamber 86 that processes the substrate 16 is formed in a cylindrical hollow portion in the inner reaction tube 84A. The process chamber 86 is configured to be able to store the boat 36.

A cylindrical heater 88 is disposed outside the reaction tube 84 so as to surround a side wall surface of the reaction tube 84. The heater 88 is vertically installed by being supported by a heater base 90.

A cylindrical furnace throat (manifold) 92 is disposed below the outer reaction tube 84B so as to be concentric with the outer reaction tube 84B. The furnace throat 92 is disposed so as to support a lower end of the inner reaction tube 84A and a lower end of the outer reaction tube 84B, and is engaged with the lower end of the inner reaction tube 84A and the lower end of the outer reaction tube 84B.

Note that an O-ring 94 serving as a seal member is disposed between the furnace throat 92 and the outer reaction tube 84B. By the furnace throat 92 being supported by the heater base 90, the reaction tube 84 is vertically installed. The reaction tube 84 and the furnace throat 92 form a reaction container.

A processing gas nozzle 96A and a purge gas nozzle 96B are connected to the furnace throat 92 so as to communicate with the inside of the process chamber 86. The processing gas supply pipe 66A is connected to the processing gas nozzle 96A. A processing gas supply source (not illustrated) or the like is connected to an upstream side of the processing gas supply pipe 66A via the MFC 64A. The purge gas supply pipe 66B is connected to the purge gas nozzle 96B. A purge gas supply source (not illustrated) or the like is connected to an upstream side of the purge gas supply pipe 66B via the MFC 64B.

The exhaust pipe 68 that exhausts the atmosphere in the process chamber 86 is connected to the furnace throat 92. The exhaust pipe 68 is disposed at a lower end of a cylindrical space 98 formed by a gap between the inner reaction tube 84A and the outer reaction tube 84B and communicates with the cylindrical space 98. The pressure sensor 70, the pressure regulator 72, and the vacuum pump 74 are connected to a downstream side of the exhaust pipe 68 in this order from an upstream side.

The disk-shaped lid body 42 capable of airtightly closing a lower end opening of the furnace throat 92 is disposed below the furnace throat 92, and an O-ring 100 serving as a seal member abutting on a lower end of the furnace throat 92 is disposed on an upper surface of the lid body 42.

The rotation mechanism 46 that rotates the boat 36 is disposed on a side of the vicinity of the center of the lid body 42 opposite to the process chamber 86. A rotation shaft 102 of the rotation mechanism 46 passes through the lid body 42 to support the boat 36 from below. In addition, the rotation mechanism 46 includes a rotation motor 46A therein, and it is configured such that the rotation motor 46A rotates the rotation shaft 102 of the rotation mechanism 46 to rotate the boat 36, thereby rotating the substrate 16.

The lid body 42 is configured to be vertically elevated by the boat elevator 38 disposed outside the reaction tube 84. It is configured such that the boat 36 can be carried into and out of the process chamber 86 by elevating the lid body 42. The carry controller 48 is electrically connected to the rotation motor 46A of the rotation mechanism 46 and the boat elevator 38.

The boat 36 is configured to align a plurality of the substrates 16 in a horizontal posture with their centers aligned with each other and to hold the substrates 16 in multiple stages. In addition, a plurality of disk-shaped heat insulating plates 104 serving as a heat insulating member is arranged in multiple stages in a horizontal posture in a lower portion of the boat 36. The boat 36 and the heat insulating plate 104 are made of, for example, a heat-resistant material such as quartz or silicon carbide. The heat insulating plate 104 is disposed in order to make it difficult to transfer heat from the heater 88 to the furnace throat 92 side.

A temperature sensor 106 serving as a temperature detector is disposed in the reaction tube 84. A temperature controller 76 is electrically connected to the heater 88 and the temperature sensor 106.

### <Operation of Substrate Processing Apparatus>

Next, as one step of a semiconductor device manufacturing process, a method of forming a thin film on the substrate 16 will be described with reference to FIGS. 1 and 2. Note that an operation of each of the units constituting the substrate processing apparatus 10 is controlled by the substrate processing apparatus controller 58.

As illustrated in FIG. 1, when the pod 18 is supplied to the load port 20 by an in-process carry device (not illustrated), the pod 18 is detected by the substrate detection sensor 56, and the pod loading/unloading port is opened by a front shutter (not illustrated). Then, the pod 18 on the load port 20 is loaded into the housing 12 from the pod loading/unloading port by the pod carry device 24.

The pod 18 loaded into the housing 12 is automatically carried onto the shelf board of the rotary pod shelf 22 by the pod carry device 24 and temporarily stored thereon. Thereafter, the pod 18 is transferred from the shelf board onto the placing table of one of the pod openers 26. Note that the pod 18 loaded into the housing 12 may be directly transferred onto the placing table of the pod opener 26 by the pod carry device 24.

A lid of the pod 18 placed on the placing table is removed by the cap attaching/detaching mechanism 30, and the substrate inlet/outlet is opened. Thereafter, the substrate 16 (see FIG. 2) is picked up from the inside of the pod 18 through the substrate inlet/outlet by a tweezer of the substrate transfer device 34A. An orientation of the substrate 16 is aligned by a notch alignment device (not illustrated), then the substrate 16 is loaded into the standby portion 50 behind the transfer chamber 32, and the boat 36 is charged with the substrate 16 (charging). The substrate transfer device 34A in which the boat 36 is charged with the substrate 16 returns to the placing table on which the pod 18 is placed, takes out the next substrate 16 from the inside of the pod 18, and the boat 36 is charged with the next substrate 16.

During the operation in which the boat 36 is charged with the substrate 16 by the substrate transfer mechanism 34 in one of the pod openers 26 (in the upper or lower stage), a different pod 18 is carried onto the placing table of the other pod opener 26 (in the lower or upper stage) from the rotary pod shelf 22 by the pod carry device 24. By the other pod 18 being transferred to the placing table, the pod 18 opening operation by the pod opener 26 is simultaneously progressed.

When the boat 36 is charged with the number of substrates 16 designated in advance, a lower end of the process furnace 44 is opened by a furnace throat shutter (not illustrated). Subsequently, the boat 36 holding the group of substrates 16 is loaded into the process furnace 44 by the lid body 42 being raised by the boat elevator 38 (boat load step).

As described above, when the boat 36 holding the plurality of substrates 16 is loaded into the process chamber 86 of the process furnace 44 (loading), as illustrated in FIG. 2, the lid body 42 is in a state of sealing a lower end of the furnace throat 92 via the O-ring 100.

Thereafter, a film forming step of forming a film on the group of substrates 16 is performed. First, the inside of the process chamber 86 is vacuum-exhausted by the vacuum pump 74 so as to have a desired pressure (degree of vacuum). At this time, (the opening degree of a valve of) the pressure regulator 72 is feedback-controlled on the basis of a pressure value measured by the pressure sensor 70. The process chamber 86 is heated by the heater 88 so as to have a predetermined temperature. At this time, a power amount to the heater 88 is feedback-controlled on the basis of a temperature value detected by the temperature sensor 106. Subsequently, the boat 36 and the substrate 16 are rotated by the rotation mechanism 46.

Next, the processing gas supplied from the processing gas supply source and controlled by the MFC 64A so as to have a desired flow rate flows through the processing gas supply pipe 66A and is introduced into the process chamber 86 from the processing gas nozzle 96A. The introduced processing gas rises in the process chamber 86, flows out from an upper end opening of the inner reaction tube 84A to the cylindrical space 98, and is exhausted from the exhaust pipe 68. The processing gas comes into contact with a surface of the substrate 16 when passing through the process chamber 86, and at this time, a thin film is deposited on the surface of the substrate 16 by thermal reaction.

When a preset processing time has elapsed, the purge gas supplied from the purge gas supply source and controlled by the MFC 64B so as to have a desired flow rate is supplied to the process chamber 86, the inside of the process chamber 86 is replaced with an inert gas, and the pressure of the process chamber 86 is returned to normal pressure.

Thereafter, the lid body 42 is lowered by the boat elevator 38, a lower end of the furnace throat 92 is opened, and the boat 36 holding the processed substrate 16 is unloaded from the lower end of the furnace throat 92 to the outside of the reaction tube 84 (boat unload step). Thereafter, the processed substrate 16 is taken out from the boat 36 by the substrate transfer device 34A and stored in the pod 18 (discharge).

After the discharge, the pod 18 storing the processed substrate 16 is unloaded to the outside of the housing 12 by a procedure substantially opposite to the above-described procedure except for the alignment step by the notch alignment device.

### <Configuration of Substrate Processing Apparatus Controller>

Next, the substrate processing apparatus controller 58 serving as a main controller will be specifically described with reference to FIG. 3.

The substrate processing apparatus controller 58 mainly includes a calculation controller 108 such as a central processing unit (CPU), a storage 114 including a RAM 110, a ROM 112, and an HDD (not illustrated), an inputter 116 such as a mouse or a keyboard, and a display 118 such as a monitor. Note that it is configured such that each piece of data can be set by the calculation controller 108, the storage 114, the inputter 116, and the display 118.

The calculation controller 108 constitutes a core of the substrate processing apparatus controller 58, executes a control program stored in the ROM 112, and executes a recipe stored in the storage 114 also constituting a recipe storage (for example, a process recipe serving as a substrate processing recipe) according to an instruction from the inputter 116.

The ROM 112 is a recording medium constituted by a flash memory, a hard disk, or the like, and stores an operation program of the calculation controller 108 that controls an operation of each member (for example, the vacuum pump 74) of the substrate processing apparatus 10 and the like. The RAM 110 (memory) functions as a work area (temporary storage) of the calculation controller 108.

Here, the substrate processing recipe (process recipe) is a recipe in which a processing condition, a processing procedure, and the like for processing the substrate 16 are defined. In addition, in a recipe file, a setting value (control value) to be transmitted to the carry controller 48, the temperature controller 76, the pressure controller 78, the gas supply controller 80, or the like, a transmission timing, and the like are set for each step of substrate processing.

The calculation controller 108 has a function of controlling the temperature and pressure in the process furnace 44, the flow rate of the processing gas introduced into the process furnace 44, and the like such that predetermined processing is performed on the substrate 16 loaded into the process furnace 44.

The carry controller 48 is configured to control carry operations of the rotary pod shelf 22, the boat elevator 38, the pod carry device 24, the substrate transfer mechanism 34, the boat 36, and the rotation mechanism 46 constituting the carry mechanism that carries the substrate 16.

The rotary pod shelf 22, the boat elevator 38, the pod carry device 24, the substrate transfer mechanism 34, the boat 36, and the rotation mechanism 46 each includes a sensor therein. When each of these sensors indicates a predetermined value, an abnormal value, or the like, the substrate processing apparatus controller 58 is notified of the fact. Note that an abnormality sign detection system of each member of the substrate processing apparatus 10 will be described in detail later.

The storage 114 has a data storage area 120 in which various types of data and the like are stored and a program storage area 122 in which various programs including a substrate processing recipe (process recipe) are stored. Various parameters related to the recipe file are stored in the data storage area 120. Various programs necessary for controlling the apparatus including the above-described substrate processing recipe (process recipe) are stored in the program storage area 122.

The display 118 of the substrate processing apparatus controller 58 includes a touch panel (not illustrated). The touch panel is configured to display an operation screen for receiving an input of an operation command to the above-described substrate carry system and substrate processing system. Note that the substrate processing apparatus controller 58 only needs to include at least the display 118 and the inputter 116, like an operation terminal (terminal device) such as a personal computer or a mobile device.

The temperature controller 76 adjusts the temperature in the process furnace 44 by controlling the temperature of the heater 88 of the process furnace 44. Note that, when the temperature sensor 106 indicates a predetermined value, an abnormal value, or the like, the substrate processing apparatus controller 58 is notified of the fact.

The pressure controller 78 controls the pressure regulator 72 such that the pressure in the process chamber 86 becomes a desired pressure at a desired timing on the basis of a pressure value detected by the pressure sensor 70. Note that, when the pressure sensor 70 indicates a predetermined value, an abnormal value, or the like, the substrate processing apparatus controller 58 is notified of the fact.

The gas supply controller 80 is configured to control the MFCs 64A and 64B such that a flowrate of the gas to be supplied into the process chamber 86 becomes a desired flow rate at a desired timing. Note that, when each of sensors (not illustrated) included in the MFCs 64A and 64B and the like indicates a predetermined value, an abnormal value, or the like, the substrate processing apparatus controller 58 is notified of the fact.

### <Substrate Processing Step>

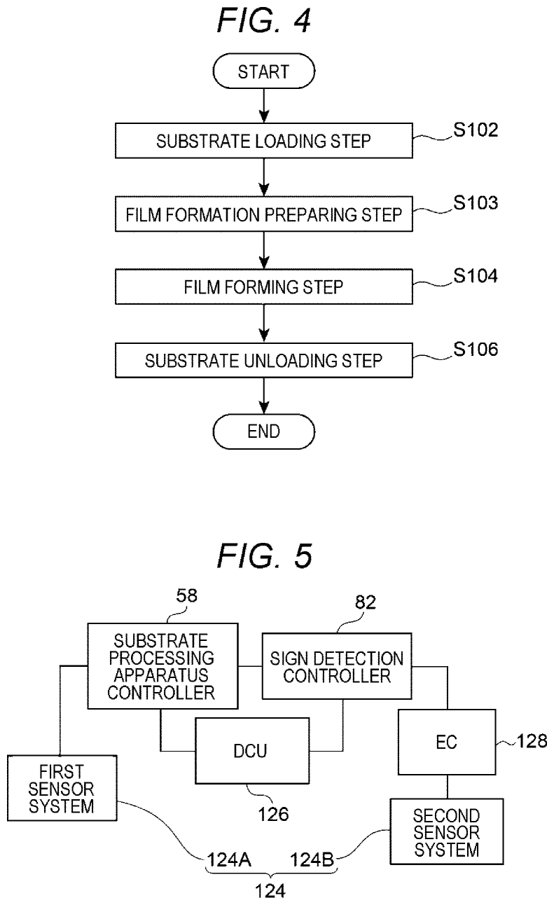

Next, an outline of a substrate processing step of processing a substrate using the substrate processing apparatus 10 of the present embodiment as a semiconductor manufacturing apparatus will be described with reference to FIG. 4. This substrate processing step is, for example, one step of a method of manufacturing a semiconductor device (IC, LSI, or the like). Note that, in the following description, an operation or processing of each of the units constituting the substrate processing apparatus 10 is controlled by the substrate processing apparatus controller 58.

Here, an example of forming a thin film on the substrate 16 by alternately supplying a source gas (first processing gas) and a reactant gas (second processing gas) to the substrate 16 will be described. Note that, for example, a predetermined film may be formed in advance on the substrate 16, and a predetermined pattern may be formed in advance on the substrate 16 or the predetermined film.

### (Substrate Loading (Boat Load) Step S102)

First, in a substrate loading step S102, the boat 36 is charged with the substrate 16 and loaded into the process chamber 86. Note that, in the substrate loading step S102, processing in which the boat 36 is charged with the substrate 16 (charging) (S102-1) and processing of loading the boat 36 charged with the substrate 16 into the process chamber 86 (loading) (S102-2) may be distinguished from each other and performed as separate steps.

### (Film Formation Preparing Step S103)

A film formation preparing step S103 is an event of vacuuming before a film forming step, and the inside of the process chamber 86 is vacuum-exhausted by the vacuum pump 74 so as to have a desired pressure (degree of vacuum). At this time, (the opening degree of a valve of) the pressure regulator 72 is feedback-controlled on the basis of a pressure value measured by the pressure sensor 70, and the pressure of the process chamber 86 is reduced from the atmospheric pressure to a predetermined pressure. The process chamber 86 is heated by the heater 88 so as to have a predetermined temperature. At this time, a power amount to the heater 88 is feedback-controlled on the basis of a temperature value detected by the temperature sensor 106. Subsequently, the boat 36 and the substrate 16 are rotated by the rotation mechanism 46.

Note that, in the film formation preparing step S103, leak check may be performed.

### (Film Forming Step S104)

In a film forming step S104, the following four steps are sequentially executed to form a thin film on a surface of the substrate 16. Note that the substrate 16 is heated to a predetermined temperature by the heater 88 during steps 1 to 4.

### [Step 1]

In step 1, an on-off valve (not illustrated) disposed in the processing gas supply pipe 66A and the pressure regulator 72 (APC valve) disposed in the exhaust pipe 68 are both opened, and a source gas whose flow rate is adjusted (flow rate is regulated or controlled) by the MFC 64A is caused to pass through the processing gas supply pipe 66A. Then, the source gas is supplied from the processing gas nozzle 96A into the process chamber 86 and exhausted from the exhaust pipe 68. At this time, the pressure in the process chamber 86 is maintained at a predetermined pressure. As a result, a first layer is formed on a surface of the substrate 16. Note that the first layer contains an element contained in the source gas.

### [Step 2]

In step 2, the on-off valve of the processing gas supply pipe 66A is closed to stop supply of the source gas. While the pressure regulator 72 (APC valve) of the exhaust pipe 68 is kept open, the inside of the process chamber 86 is exhausted by the vacuum pump 74, and the residual gas is removed from the inside of the process chamber 86. In addition, the on-off valve disposed in the purge gas supply pipe 66B is opened to supply an inert gas into the process chamber 86 to purge the inside of the process chamber 86, and the residual gas in the process chamber 86 is discharged to the outside of the process chamber 86.

### [Step 3]

In step 3, an on-off valve (not illustrated) disposed in the purge gas supply pipe 66B and the pressure regulator 72 (APC valve) disposed in the exhaust pipe 68 are both opened, and a reactant gas whose flow rate is adjusted by the MFC 64B is caused to pass through the purge gas supply pipe 66B. Then, the reactant gas is supplied from the purge gas nozzle 96B into the process chamber 86 and exhausted from the exhaust pipe 68. At this time, the pressure in the process chamber 86 is maintained at a predetermined pressure. As a result, the first layer formed on the surface of the substrate 16 by the source gas reacts with the reactant gas, and the first layer is modified by an action of the reactant gas to form a second layer on the substrate 16. Note that the second layer contains an element contained in the source gas and an element contained in the reactant gas.

### [Step 4]

In step 4, the on-off valve of the purge gas supply pipe 66B is closed to stop supply of the reactant gas. While the pressure regulator 72 (APC valve) of the exhaust pipe 68 is kept open, the inside of the process chamber 86 is exhausted by the vacuum pump 74, and the residual gas is removed from the inside of the process chamber 86. In addition, an inert gas is supplied into the process chamber 86, and the inside of the process chamber 86 is purged again.

Steps 1 to 4 described above are defined as one cycle, and this cycle is performed a predetermined number of times, preferably a plurality of times to form a thin film having a predetermined film thickness on the substrate 16.

As the source gas, for example, a chlorosilane-based gas such as a monochlorosilane (SiH₃Cl, abbreviation: MCS) gas, a dichlorosilane (SiH₂Cl₂, abbreviation: DCS) gas, a trichlorosilane (SiHCl₃, abbreviation: TCS) gas, a tetrachlorosilane (SiCl₄, abbreviation: STC) gas, a hexachlorodisilane gas (Si₂Cl₆, abbreviation: HCDS) gas, or an octachlorotrisilane (Si₃Cl₈, abbreviation: OCTS) gas can be used. In addition, as the source gas, for example, a fluorosilane-based gas such as a tetrafluorosilane (SiF₄) gas, a bromosilane-based gas such as a tetrabromosilane (SiBr₄) gas, or an iodosilane-based gas such as a tetraiodosilane (SiI₄) gas can also be used. In addition, as the source gas, for example, an aminosilane-based gas such as a tetrakis(dimethylamino) silane (Si[N(CH₃)₂]₄, abbreviation: 4DMAS) gas, a tris(dimethylamino) silane (Si[N(CH₃)₂]₃H, abbreviation: 3DMAS) gas, a bis(diethylamino) silane (Si[N(C₂H₅)₂]₂H₂, abbreviation: BDEAS) gas, or a bis(tertiary butylamino) silane (SiH₂[NH(C₄H₉)]₂, abbreviation: BTBAS) gas can also be used. One or more of these can be used as the source gas.

As the reactant gas, for example, an oxidizing gas such as an oxygen (O₂) gas, a nitrous oxide (N₂O) gas, a nitrogen monoxide (NO) gas, a nitrogen dioxide (NO₂) gas, an ozone (O₃) gas, water vapor (H₂O gas), a carbon monoxide (CO) gas, or a carbon dioxide (CO₂) gas, or a nitriding gas such as an ammonia (NH₃) gas, a hydrazine (N₂H₄) gas, a diazene (N₂H₂) gas, or an N₃H₈ gas can be used. One or more of these can be used as the reactant gas.

As the inert gas, for example, a nitrogen (N₂) gas can be used, and in addition to this, a rare gas such as an argon (Ar) gas, a helium (He) gas, a neon (Ne) gas, or a xenon (Xe) gas can be used. One or more of these can be used as the inert gas.

When an oxidizing gas is used as the reactant gas, a silicon oxide film (SiO film) can be formed as a thin film on the substrate 16. When a nitriding gas is used as the reactant gas, a silicon nitride film (SiN film) can be formed on the substrate 16. When an oxidizing gas and a nitriding gas are used as the reactant gas, a silicon oxynitride film (SiON film) can be formed as a thin film on the substrate 16.

### (Substrate Unloading (Boat Unload) Step S106)

In a substrate unloading step S106, the boat 36 on which the substrate 16 having the thin film formed thereon is placed is unloaded from the process chamber 86 by the boat elevator 38 (unloading). Note that processing of discharging the substrates 16 from the boat 36 by the substrate transfer device 34A (discharge), which is a next step, may be included in the substrate unloading step (S106).

### <Control System in Present Embodiment>

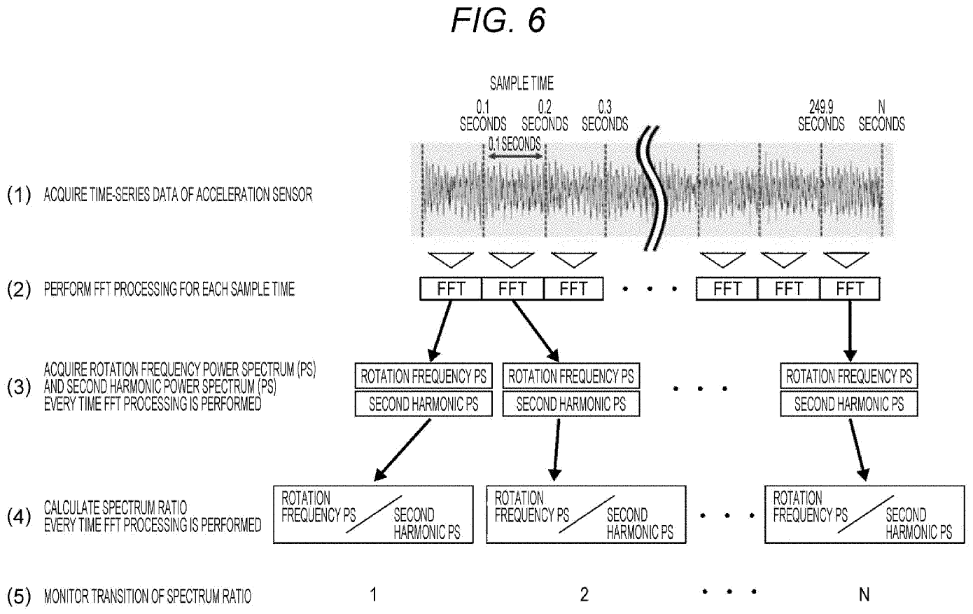

Next, a control system that detects an abnormality sign (failure sign) of each member of the substrate processing apparatus 10 will be described with reference to FIGS. 5 and 6. Note that, hereinafter, the control system will be described using an example in which a thin film is formed on the substrate 16 by the substrate processing apparatus 10.

As illustrated in FIG. 5, the control system includes the substrate processing apparatus controller 58 serving as a main controller, the sign detection controller 82 serving as a sign detector, various sensors 124, a data collection unit (hereinafter abbreviated as DCU) 126, and an edge controller (hereinafter abbreviated as EC) 128. Note that these components constituting the control system are connected to each other in a wired or wireless manner.

The substrate processing apparatus controller 58 is connected to a host computer (not illustrated) including a customer host computer and an operation portion (not illustrated). The operation portion is configured to be able to exchange various types of data (sensor data and the like) acquired by the substrate processing apparatus controller 58 with the host computer.

The sign detection controller 82 acquires sensor data from sensors of various members disposed in the substrate processing apparatus 10 and facilities attached thereto, and monitors a state of the substrate processing apparatus 10. Specifically, the sign detection controller 82 calculates a numerical index using data from the various sensors 124, compares the numerical index with a predetermined threshold, and detects an abnormality sign (that is, a failure sign). Note that the sign detection controller 82 includes a sign detection program that detects occurrence of an abnormality sign on the basis of movement of sensor data therein.

In addition, the sign detection controller 82 has two systems: a system directly connected to the substrate processing apparatus controller 58 and a system connected to the substrate processing apparatus controller 58 via the DCU 126. Therefore, when the sign detection controller 82 detects an abnormality sign, the sign detection controller 82 directly sends a signal to the substrate processing apparatus controller 58 without causing the signal to pass through the DCU 126 to generate an alarm, and information of sensor data of a sensor disposed in a member in which an abnormality sign is recognized can be displayed on a screen of the display 118 (see FIG. 3).

The various sensors 124 are sensors disposed in various members disposed in the substrate processing apparatus 10 and facilities attached thereto (for example, the pressure sensor 70 and the temperature sensor 106), and detect a flow rate, a concentration, a temperature, a humidity (dew point), a pressure, a current, a voltage, a torque, a vibration, a position, a rotation speed, and the like of each of the members.

The DCU 126 collects and accumulates data of the various sensors 124 during execution of the process recipe. The EC 128 temporarily takes in sensor data as necessary depending on the type of sensor, performs processing such as fast Fourier transform (hereinafter, abbreviated as FFT) on the raw data, and then transmits the processed data to the sign detection controller 82.

The various sensors 124 are divided into a first sensor system 124A and a second sensor system 124B having different transmission paths. The first sensor system 124A is a system that takes in raw data in real time in units of 0.1 seconds, and the raw data is transmitted from the first sensor system 124A to the sign detection controller 82 in real time via the substrate processing apparatus controller 58 and the DCU 126. The first sensor system 124A includes, for example, sensors such as a temperature sensor, a pressure sensor, and a gas flow rate sensor.

Meanwhile, the second sensor system 124B is a system in which only a portion necessary for analysis is extracted by performing processing such as FFT in the EC 128 and data is transmitted in a processed file format, and the processed data is transmitted from the second sensor system 124B to the sign detection controller 82 via the EC 128. The second sensor system 124B includes, for example, the acceleration sensor 75. Since vibration data from the acceleration sensor 75 is accumulated in units of milliseconds, a minute change can be captured. For example, even if the magnitude of a vibration itself is the same, the magnitude of the vibration may vary depending on frequency, and even in this case, a minute change in the vibration in units of milliseconds (for example, 0.1 seconds) can be captured from a frequency distribution. As a result, it is possible to capture data fluctuation before a failure occurs, and therefore, an abnormality sign can be detected.

Since the vibration data from the acceleration sensor 75 is accumulated in units of milliseconds, the amount of the data is enormous, and if the data is transmitted to the sign detection controller 82 as it is, a large amount of storage capacity of the sign detection controller 82 is consumed. The vibration data is subjected to processing such as FFT and used for analysis. Therefore, by causing the EC 128 to perform the processing in advance, the information amount can be reduced, and the vibration data can be transmitted to the sign detection controller 82 as a format of data that is easily analyzed.

Hereinafter, an embodiment of an abnormality sign determining step of the vacuum pump 74 serving as a member of the substrate processing apparatus 10 using the above-described control system will be specifically described.

### [Original Data Constituting Non-Normality]

A substrate processing sequence includes, for example, many events having respective purposes, such as loading of the substrate 16 into the process chamber 86, vacuuming the inside of the process chamber 86, temperature elevation, purging with an inert gas, waiting for temperature elevation, processing (for example, film formation) of the substrate 16, gas replacement in the process chamber 86, returning the pressure to atmospheric pressure, and unloading of the substrate 16 after processing. Note that the above events are examples of the substrate processing sequence, and there is a case where each of the events is further finely divided.

In the present embodiment, values of one or more sensors in one or more specific events among these events are used as original data for calculating “non-normality”, which is a numerical index in an algorithm, without using all pieces of sensor data in the sequence. In addition, a non-normality value for each Run is monitored, and an abnormality sign of each member of the substrate processing apparatus 10 is detected. In this way, by using only data of the specific event, a data accumulation amount can be saved.

For example, an abnormality sign of a member is easily detected at a timing when a large load is applied to the member. A step of reducing the pressure of the process chamber 86 from the atmospheric pressure to a predetermined pressure, that is, a vacuuming start time or a time period of several minutes after start of vacuuming during which the pressure is close to the atmospheric pressure corresponds to a timing when a large load is applied to the member.

In addition, one substrate processing apparatus 10 is in charge of a plurality of steps, and there is a case where different processing recipes such as those having different film-forming conditions are mixed and started. Since the source gas flows at the time of film formation of the substrate 16, the source gas may react or may be thermally decomposed to generate a solid material, which may apply a load to the member. Therefore, monitoring during the film forming event is also effective for detecting an abnormality sign.

Meanwhile, when Runs having different film forming events are mixed, since conditions are different between the different film forming events, it is difficult to perform direct comparison, and a temporal change is monitored only for Runs having the same film forming event. A monitoring target may be dispersed, and it may be difficult to understand a tendency.

The vacuuming event before substrate processing described above is often common even when a subsequent substrate processing event is different. That is, even when recipes having a plurality of different film-forming conditions are started by the same apparatus, by monitoring a state at start of vacuuming common to the Runs and acquiring sensor data, it is possible to find a temporal change of the same state without depending on contents of substrate processing, and to perform highly accurate prediction.

In addition, monitoring may be performed in the boat unloading step in which the rotation frequency of the member is different from that in the film forming step.

### [Calculation Example of Non-Normality]

Here, calculation examples of non-normality in a case where sensor data of the acceleration sensor 75 is used will be described.

First, in a case where presence or absence of an abnormality sign is determined using the sensor data (vibration data) of the acceleration sensor 75, the following procedure is performed as illustrated in FIG. 6.

(1) Vibration data (raw data) detected by the acceleration sensor 75 is acquired from among pieces of sensor data in a designated step among steps constituting the process recipe, for example, in a first patch. In the present embodiment, the vibration data of the acceleration sensor 75 is acquired for each of the X-axis, the Y-axis, and the Z-axis and is vibration data in each of the three axial directions.

(2) FFT processing is performed for each sample time on the acquired time-series vibration data of each of the X-axis, Y-axis, and Z-axis. The FFT processing is performed on the entire vibration data within a sample time (0.1 seconds as an example in the present embodiment).

(3) Every time FFT processing is performed, the magnitude of vibration at a frequency (hereinafter, reference frequency) of the rotation frequency (the number of rotations per second) of a rotor of the member (hereinafter, referred to as “rotation frequency power spectrum”) and the magnitude of vibration at a frequency (hereinafter, comparison frequency) twice the rotation frequency of the rotor of the member (hereinafter, referred to as “second harmonic power spectrum”) are acquired. Note that, as the rotation frequency of the rotor of the member, the rotation frequency at which the member is controlled in the designated step is used.

(4) A ratio between the rotation frequency power spectrum and the second harmonic power spectrum (rotation frequency power spectrum/second harmonic power spectrum, hereinafter referred to as “power spectrum ratio”) is calculated every time FFT processing is performed.

(5) Transition of the calculated power spectrum ratio is monitored.

(6) In a case where the power spectrum ratio exceeds a preset threshold (100 as an example in the present embodiment), presence of an abnormality sign is detected. The threshold (abnormality sign threshold) is set on the basis of the power spectrum ratio during the designated step at a normal time and past abnormality occurrence data. Note that the threshold is individually set for the power spectrum ratio obtained from data of each of the X-axis, the Y-axis, and the Z-axis. The set thresholds may be the same as or different from each other.

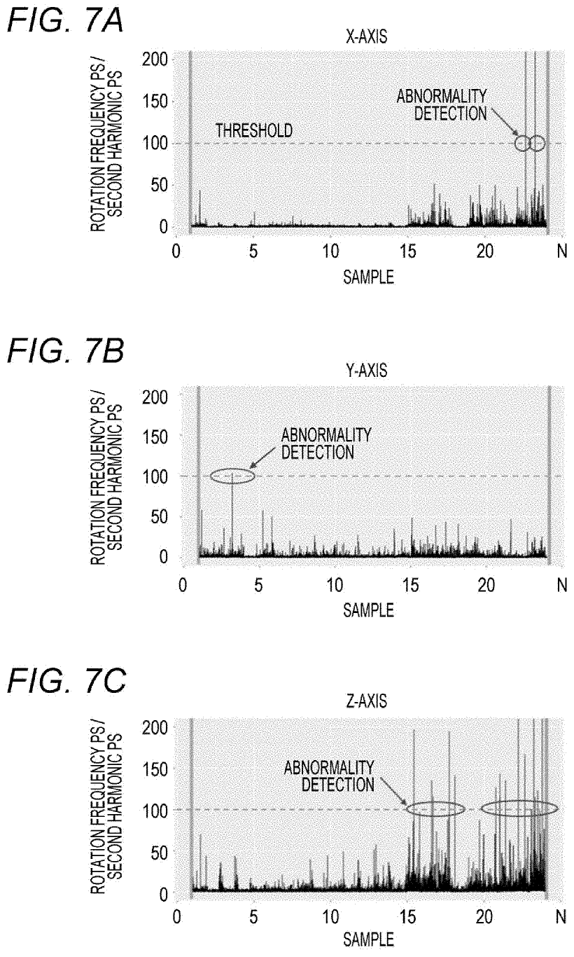

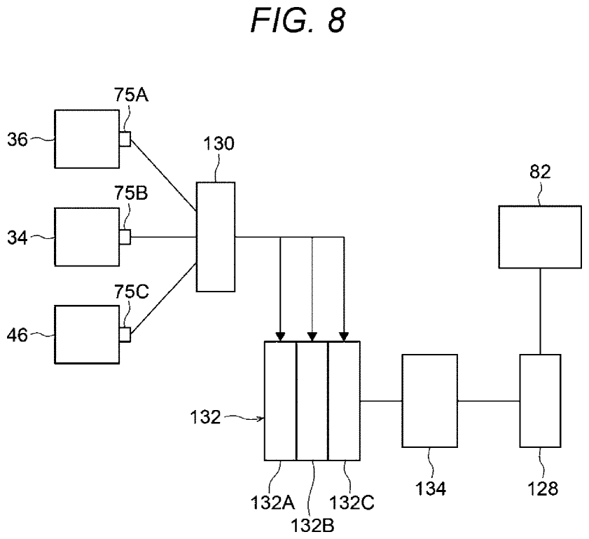

FIGS. 7A to 7C each illustrate a graph of transition of the power spectrum ratio obtained from the vibration data of the designated step in FIG. 6. FIG. 7A is a graph for the X-axis, FIG. 7B is a graph for the Y-axis, and FIG. 7C is a graph for the Z-axis. The number of pieces of data N of the power spectrum ratio is obtained by the number of sample times, and it is possible to capture a fine change in the power spectrum ratio for each sample time (every 0.1 seconds in the present embodiment). As a result, abnormality sign detection can be performed at an appropriate timing before the member stops.

In FIGS. 7A to 7C, the threshold 100 is set for each of the X-axis, the Y-axis, and the Z-axis, but another threshold may be set. For example, the threshold 100 can be set for the X-axis and the Y-axis, and a threshold 200 can be set for the Z-axis. In this way, by individually setting the threshold for each of the axes, it is possible to perform appropriate determination according to a characteristic of generation of vibration depending on a direction.

In addition, when presence of an abnormality sign is determined for each of the X-axis, the Y-axis, and the Z-axis, a limit may be set for the number of times the power spectrum ratio exceeds the threshold. That is, the number of times the power spectrum ratio exceeds the threshold is set for each of the X-axis, the Y-axis, and the Z-axis, and it is determined that there is an abnormality sign when the number of times is equal to or more than the set number of times. For example, in the graph of FIG. 7A, there is a sample in which the power spectrum ratio is equal to or more than the threshold two times. It is determined that there is an abnormality sign in a case where the number of times is set to two or more times, and it is not determined that there is an abnormality sign in a case where the number of times is set to three or more times. The number of times can be individually set for the X-axis, the Y-axis, and the Z-axis, and the same number of times may be set or different numbers of times may be set. For example, the number of times can be set to two times for the X-axis, one time for the Y-axis, and ten times for the Z-axis. In this way, by setting a limit to the number of times, it is possible to perform appropriate determination excluding data fluctuation due to unexpected noise or the like.

Presence of an abnormality sign in the vibration data can be determined by the following different methods as an example.

(1) In a case where the power spectrum ratio exceeds the threshold on any one of the X-axis, the Y-axis, and the Z-axis, it is determined that there is an abnormality sign.

(2) In a case where the power spectrum ratio exceeds the threshold on two axes among the X-axis, the Y-axis, and the Z-axis, it is determined that there is an abnormality sign.

(3) In a case where the power spectrum ratio exceeds the threshold on the X-axis or the Z-axis, it is determined that there is an abnormality sign (even when the power spectrum ratio exceeds the threshold on the Y-axis, it is not determined that there is an abnormality sign). In this case, the threshold does not have to be set for the axis (Y axis) that is not selected, and only monitoring may be performed.

By selecting (1) and (2) regarding determination of presence of an abnormality sign, it is possible to perform appropriate determination excluding data fluctuation due to unexpected noise or the like.

By selecting (3) regarding determination of presence of an abnormality sign, information on vibration of the rotor in the rotation shaft direction can be excluded from the determination on the abnormality sign. As illustrated in FIG. 7B, since the vibration of the rotor in the rotation shaft (Y-axis) direction has a characteristic different from the vibrations in the other directions, it is possible to perform appropriate determination by excluding the vibration in the rotation shaft (Y-axis) direction from the determination on the abnormality sign.

### [Display of Analysis Screen for Abnormality Sign Detection]

An analysis screen for abnormality sign detection can be displayed on the display 118 (see FIG. 3) of the substrate processing apparatus controller 58. For this reason, transition of non-normality, the threshold, the number of times the power spectrum ratio exceeds the threshold, and the like can be visually observed, and a wearing state of the member can be confirmed with the non-normality.

### (Action and Effect)

According to the above embodiment, the substrate processing apparatus 10 includes the control system that detects an abnormality sign of a member, and by detecting the abnormality sign of the member by the control system, it is possible to find an appropriate time before a replacement time or a maintenance time of the target member.

As a result, it is possible to take measures such as replacement before the member fails, and it is possible to reduce a replacement frequency by using the member until immediately before the member fails. In addition, by preventing failure during substrate processing, it is possible to improve an apparatus operation ratio, to prevent a decrease in a yield rate of a product (substrate 16), and to reduce unnecessary maintenance time.

In addition, according to the above embodiment, the sign detection controller 82 that detects an abnormality sign is connected to the substrate processing apparatus controller 58. Therefore, data can be acquired and analyzed only in a specific substrate processing sequence in which an abnormality sign is easily detected.

In addition, according to the above embodiment, the vibration data acquisition step and the abnormality sign detection step can be executed in parallel with the substrate processing step, and an abnormality sign of a member can be detected in real time.

In addition, regarding failure sign detection of a member, vibration data is subjected to FFT processing for each sample time to obtain data of a power spectrum ratio in a designated step. Therefore, it is possible to acquire a large number of indices for an abnormality sign of a member (the number of times FFT process is performed) within the designated step. As a result, a fine change in the spectrum ratio in the designated step or process can be captured.

Note that, in the present embodiment, a ratio between a power spectrum of vibration at a rotation frequency of a member and a power spectrum of vibration at a rotation frequency twice the rotation frequency of the member is used as an index of non-normality, but the index of non-normality is not limited thereto. A ratio between a power spectrum of vibration at a rotation frequency of a member and a power spectrum of vibration at a rotation frequency of an integral multiple such as twice or three times the rotation frequency of the member may be used as the index of non-normality.

### (Other Embodiment)

In the above-described embodiment, an example in which the acceleration sensor 75 is disposed in the vacuum pump 74 has been described, but the position at which the acceleration sensor is disposed is not limited thereto. The acceleration sensor can be attached to another constituent member constituting the substrate processing apparatus 10, can acquire vibration data, and can detect an abnormality sign of each attached constituent member. Note that a series of events of acquiring vibration data and detecting an abnormality sign is similar to that in the above-described embodiment, and description thereof is omitted here.

For example, a case will be described in which the acceleration sensor 75 is attached to the vacuum pump 74 as described above, an acceleration sensor 75A is attached to the substrate transfer mechanism 34 that carries the substrate (wafer) 16 between the boat 36 (substrate holder) and the pod 18 (substrate container), an acceleration sensor 75B is attached to the boat elevator 38 that elevates the boat 36, and an acceleration sensor 75C is attached to the rotation mechanism 46 that rotates the boat 36.

As illustrated in FIG. 8, the acceleration sensor 75A is attached to the substrate transfer mechanism 34, the acceleration sensor 75B is attached to the boat elevator 38, and the acceleration sensor 75C is attached to the rotation mechanism 46. The acceleration sensors 75A to 75C are attached to positions where vibrations can be measured when the substrate transfer mechanism 34, the boat elevator 38, and the rotation mechanism 46 are driven, and measure vibrations in three orthogonal axial directions (X-axis, Y-axis, and Z-axis), respectively.

The acceleration sensors 75A to 75C are electrically connected to a selector 130, and transmit vibration data acquired by measurement to the selector 130. The selector 130 switches vibration data to be acquired among pieces of the vibration data from the acceleration sensors 75A to 75C according to a timing of each step. The selector 130 is connected to charge amplifiers 132A, 132B, and 132C. The charge amplifiers 132A, 132B, and 132C process the vibration data on the X-axis, the vibration data on the Y-axis, and the vibration data on the Z-axis from the acceleration sensors 75A to 75C, respectively. The charge amplifiers 132A, 132B, and 132C (collectively referred to as “charge amplifier 132”) are connected to a programmable logic controller (PLC) 134, and the PLC 134 is connected to the EC 128. The acceleration sensors 75A to 75C, the selector 130, the charge amplifier 132, and the PLC 134 are included in the second sensor system 124B described above (see FIG. 5).

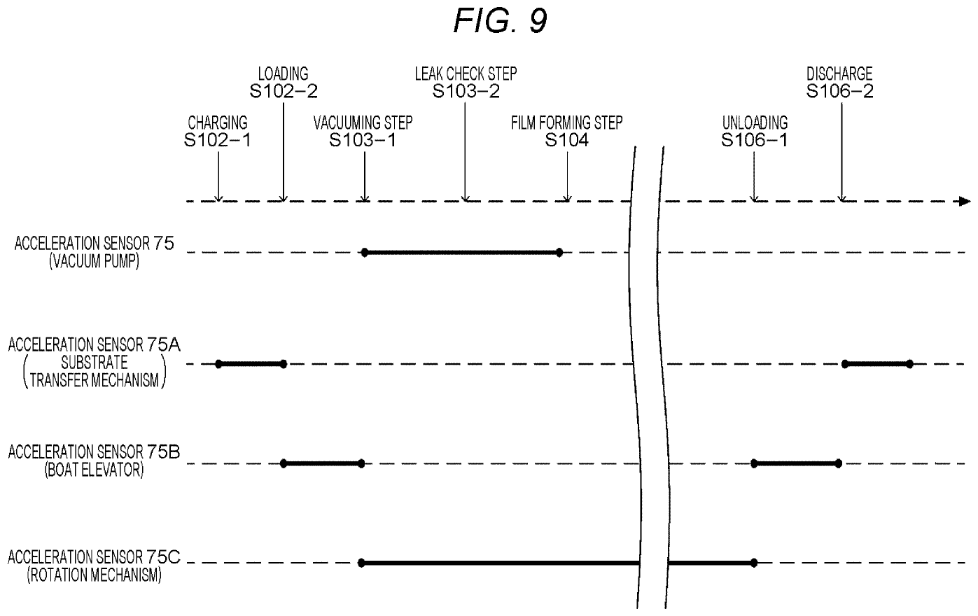

Next, acquisition of vibration data in the acceleration sensor 75 (attached to the vacuum pump 74), the acceleration sensor 75A (attached to the substrate transfer mechanism 34), the acceleration sensor 75B (attached to the boat elevator 38), and the acceleration sensor 75C (attached to the rotation mechanism 46) will be described with reference to a timing chart of FIG. 9.

The vibration data from the acceleration sensor 75 is acquired in the film formation preparing step S103 (vacuuming step S103-1 and leak check step S103-2) in which the vacuum pump 74 is driven. In particular, a step of reducing the pressure of the process chamber 86 from the atmospheric pressure to a predetermined pressure, that is, a vacuuming start time or a time period of several minutes after start of vacuuming during which the pressure is close to the atmospheric pressure is a timing when a large load is applied to the member. An abnormality in the vacuum pump 74 is easily detected and vibration data is preferably acquired at the timing. In addition, in the film formation preparing step S103, there are many common matters even if there is a difference in a subsequent substrate processing, and thus vibration data is preferably acquired here.

The vibration data (transfer member vibration data) is acquired from the acceleration sensor 75A when the substrate transfer mechanism 34 is driven. Specifically, the vibration data (transfer member vibration data) is acquired from the acceleration sensor 75A during processing in which the boat 36 is charged with the substrates 16 (charging) (S102-1) and processing in which the substrates 16 is discharged from the boat 36 (discharge) (S106-2). Note that the vibration data (transfer member vibration data) may be acquired from the acceleration sensor 75A during only one of charging and discharge.

The vibration data (elevating member vibration data) is acquired from the acceleration sensor 75B when the boat elevator 38 is driven. Specifically, the vibration data (raising and lowering member vibration data) is acquired from the acceleration sensor 75B at the time of processing in which the boat 36 charged with the substrates 16 is loaded into the process chamber 86 (loading) (S102-2) and at the time of processing in which the boat 36 on which the substrates 16 having a thin film formed thereon is placed is unloaded from the process chamber 86 (unloading) (S106-1). Note that the vibration data (raising and lowering member vibration data) may be acquired from the acceleration sensor 75B during only one of loading and unloading.

The vibration data (rotation member vibration data) is acquired from the acceleration sensor 75C when the rotation mechanism 46 is driven and the boat elevator 38 is not driven. Specifically, the vibration data (rotation member vibration data) is acquired from the acceleration sensor 75C in the film formation preparing step 5103 (vacuuming step S103-1 and leak check step S103-2) and in the film forming step 5104. In the film forming step S104, there is a change in the flow rate or the like of a gas supplied to the process chamber, but it is considered that an influence thereof on the rotation mechanism 46 is small. Note that the vibration data (rotation member vibration data) may be acquired from the acceleration sensor 75C in only one of the film formation preparing step and the film forming step. In particular, at the time of the leak check step S103-2, since a gas is not supplied into the process chamber or exhausted from the process chamber, and the process chamber is in a stable state, the vibration data is preferably acquired in the leak check step S103-2.

Since pieces of the vibration data from the three acceleration sensors of the acceleration sensors 75A to 75C are acquired at different times, the charge amplifier 132 and the PLC 134 can be shared by switching the charge amplifier 132 and the PLC 134 therebetween for use. In addition, an accumulation amount of the vibration data acquired by the acceleration sensors 75A to 75C can be reduced.

The acquired vibration data is used as original data constituting non-normality, and an abnormality sign can be detected by the above-described procedure illustrated in FIG. 6.

As described above, the vibration data from the acceleration sensor 75 (attached to the vacuum pump 74), the acceleration sensor 75A (attached to the substrate transfer mechanism 34), the acceleration sensor 75B (attached to the boat elevator 38), and the acceleration sensor 75C (attached to the rotation mechanism 46) is acquired, and the vibration data acquisition step and the abnormality sign detection step are executed in parallel with the substrate processing step, whereby an abnormality sign of each member can be detected in real time.

### (Others)

The embodiment of the present disclosure has been described in detail above, but the present disclosure is not limited to the embodiment described above, and various modifications can be made without departing from the gist of the present disclosure.

For example, in the above-described embodiment, an example in which a thin film is formed on the substrate 16 has been described. However, the present disclosure is not limited to such an aspect, and can also be suitably applied to, for example, a case where processing such as oxidizing, diffusing, annealing, or etching is performed on a thin film or the like formed on the substrate 16.

In addition, in the above-described embodiment, an example has been described in which a thin film is formed using the substrate processing apparatus 10 including the hot wall type process furnace 44, but the present disclosure is not limited thereto, and can also be suitably applied to a case where a thin film is formed using a substrate processing apparatus including a cold wall type process furnace. Furthermore, in the above-described embodiment, an example has been described in which a thin film is formed using the batch-type substrate processing apparatus 10 that processes a plurality of substrates 16 at one time. However, the present disclosure is not limited thereto, and can also be suitably applied to a case where a film is formed using a single-wafer-type substrate processing apparatus that processes one or several substrates 16 at one time.

In addition, the present disclosure can be applied not only to a semiconductor manufacturing apparatus that processes a semiconductor substrate, such as the substrate processing apparatus 10 according to the above-described embodiment but also to a liquid crystal display (LCD) manufacturing apparatus that processes a glass substrate.

The present disclosure provides a technique capable of detecting an abnormality sign of a member.
FIG. 3
108 CALCULATION CONTROLLER
118 DISPLAY
116 INPUTTER
114 STORAGE
120 DATA STORAGE AREA
122 PROGRAM STORAGE AREA
FIG. 4
START
S102 SUBSTRATE LOADING STEP
S103 FILM FORMATION PREPARING STEP
S104 FILM FORMING STEP
S106 SUBSTRATE UNLOADING STEP
END
FIG. 5
124A FIRST SENSOR SYSTEM
124B SECOND SENSOR SYSTEM
58 SUBSTRATE PROCESSING APPARATUS CONTROLLER
82 SIGN DETECTION CONTROLLER
FIG. 6
(1) ACQUIRE TIME-SERIES DATA OF ACCELERATION SENSOR
(2) PERFORM FFT PROCESSING FOR EACH SAMPLE TIME
(3) ACQUIRE ROTATION FREQUENCY POWER SPECTRUM (PS) AND SECOND HARMONIC POWER SPECTRUM (PS) EVERY TIME FFT PROCESSING IS PERFORMED
(4) CALCULATE SPECTRUM RATIO EVERY TIME FFT PROCESSING IS PERFORMED
(5) MONITOR TRANSITION OF SPECTRUM RATIO
SAMPLE TIME
0.1 SECONDS
0.2 SECONDS
0.3 SECONDS
249.9 SECONDS
N SECONDS
ROTATION FREQUENCY PS
SECOND HARMONIC PS
FIG. 7A
ROTATION FREQUENCY PS/SECOND HARMONIC PS
X-AXIS
SAMPLE
THRESHOLD
ABNORMALITY DETECTION
FIG. 7B
ROTATION FREQUENCY PS/SECOND HARMONIC PS
Y-AXIS
SAMPLE
ABNORMALITY DETECTION
FIG. 7C
ROTATION FREQUENCY PS/SECOND HARMONIC PS
Z-AXIS
SAMPLE
ABNORMALITY DETECTION
FIG. 9
S102-1 CHARGING
S102-2 LOADING
S103-1 VACUUMING STEP
S103-2 LEAK CHECK STEP
S104 FILM FORMING STEP
S106-1 UNLOADING
S106-2 DISCHARGE
ACCELERATION SENSOR 75 (VACUUM PUMP)
ACCELERATION SENSOR 75A (SUBSTRATE TRANSFER MECHANISM)
ACCELERATION SENSOR 75B (BOAT ELEVATOR)
ACCELERATION SENSOR 75C (ROTATION MECHANISM)

What is claimed is:

1. A method of manufacturing a semiconductor device on a substrate by executing a process recipe including a plurality of steps, the method comprising:
(a)acquiring vibration data of a member that exhausts an atmosphere in a process chamber that processes the substrate from a vibration sensor while executing the process recipe; and
(b)detecting presence of an abnormality sign in a case where a ratio between a magnitude of vibration at a rotation frequency of the member and a magnitude of vibration at a comparison frequency that is an integral multiple of the rotation frequency exceeds a preset abnormality sign threshold on a basis of the acquired vibration data.

2. The method of claim 1, wherein the magnitude of vibration at a rotation frequency and the magnitude of vibration at a comparison frequency are acquired on a basis of a result of performing fast Fourier transform processing on the vibration data.

3. The method of claim 2, wherein a sample time of the fast Fourier transform processing is an entire time of time-series data to be subjected to the fast Fourier transform processing.

4. The method of claim 1, wherein the comparison frequency is a secondary rotation frequency that is twice the rotation frequency.

5. The method of claim 1, wherein presence of an abnormality sign is detected in a case where the ratio exceeds the abnormality sign threshold a preset number of times in (b).

6. The method of claim 1, wherein the vibration sensor is an acceleration sensor capable of measuring vibrations in three axial directions of an X-axis, a Y-axis, and a Z-axis orthogonal to each other.

7. The method of claim 6, wherein an abnormality sign of the member can be detected in each of the three axial directions of the X-axis, the Y-axis, and the Z-axis.

8. The method of claim 7, wherein the abnormality sign threshold is individually set for each of the three axial directions of the X-axis, the Y-axis, and the Z-axis.

9. The method of claim 6, wherein the Z-axis is disposed in a direction along a vertical axis, and the Y-axis is disposed in a direction along a rotation shaft.

10. The method of claim 9, wherein vibration in a direction along the rotation shaft is excluded from data for detecting an abnormality sign in (b).

11. The method of claim 10, wherein a warning is issued in a case where presence of an abnormality sign is detected in vibration data along a plurality of axes in (b).

12. A non-transitory computer-readable recording medium storing a program that causes a substrate processing apparatus that processes a substrate by executing a process recipe including a plurality of steps, by a computer, to perform:
acquiring vibration data of a member that exhausts an atmosphere in a process chamber that processes the substrate from a vibration sensor while executing the process recipe; and
determining presence of an abnormality sign in a case where a ratio between a magnitude of vibration at a rotation frequency of the member and a magnitude of vibration at a comparison frequency that is an integral multiple of the rotation frequency exceeds a preset abnormality sign threshold on a basis of the acquired vibration data.

13. A substrate processing apparatus that processes a substrate by executing a process recipe including a plurality of steps, the substrate processing apparatus comprises:
a vibration data acquisitor that acquires vibration data of a member that exhausts an atmosphere in a process chamber that processes the substrate from a vibration sensor while executing the process recipe; and
an abnormality sign detector that detects presence of an abnormality sign in a case where a ratio between a magnitude of vibration at a rotation frequency of the member and a magnitude of vibration at a comparison frequency that is an integral multiple of the rotation frequency exceeds a preset abnormality sign threshold on a basis of the acquired vibration data.

14. The method of claim 1, further comprising a substrate processing step (c) at least including: (c-1) loading a substrate into the process chamber; (c-2) forming a film on the substrate in the process chamber; and (c-3) unloading the substrate to an outside of the process chamber, wherein at least one of (a) and (b) is executed in parallel with execution of (c).

15. The method of claim 14, wherein (c) further includes at least one of a step in which a substrate holder is charged with the substrate and a step in which the substrate is discharged from the substrate holder.

16. The method of claim 1, wherein:
(a) is configured to acquire vibration data of at least one among constituent members constituting the substrate processing apparatus from the vibration sensor, and
at least one of an exhaust member that exhausts an atmosphere in the process chamber, a carry member that carries the substrate between a substrate holder and a substrate container, an elevating member that elevates the substrate holder, and a rotation member that rotates the substrate holder is selected as the constituent members.

17. The non-transitory computer-readable recording medium according to claim 12, the program causing the substrate processing apparatus to perform a substrate processing procedure at least including: a substrate loading procedure of loading the substrate into the process chamber; a film forming procedure of forming a film on the substrate in the process chamber; and a substrate unloading procedure of unloading the substrate to an outside of the process chamber in parallel with execution of at least one of the procedure of acquiring the vibration data and the procedure of determining presence of the abnormality sign.

18. The substrate processing apparatus according to claim 13, wherein
the process recipe includes a substrate processing step at least including: a substrate loading step of loading the substrate into the process chamber; a film forming step of forming a film on the substrate in the process chamber; and a substrate unloading step of unloading the substrate to an outside of the process chamber, and
the substrate processing apparatus comprises a controller that executes at least one of vibration data acquisition by the vibration data acquisitor and abnormality sign detection by the abnormality sign detector in parallel with execution of the substrate processing step.

19. The substrate processing apparatus according to claim 13, wherein the vibration data acquisitor acquires the vibration data as transfer member vibration data when a substrate holder is charged with the substrate and/or when the substrate is discharged from the substrate holder, acquires the vibration data as elevating member vibration data when the substrate holder is elevated, and acquires the vibration data as rotation member vibration data when the substrate holder is rotated and the substrate holder is not elevated.
